(19) United States
(12) Patent Application Publication
(10) Pub. No.: US 2014/0238465 A1
(43) Pub. Date: Aug. 28, 2014

(54) CPV TRACKING USING PARTIAL CELL VOLTAGES

(71) Applicant: Suncore Photovoltaics, Inc., Irwindale, CA (US)

(72) Inventors: Ori Kost, Omer (IL); Ilan Lozovsky, Herzliya (IL); Rani Moran, Rehovot (IL); Haim Chayet, Nes Ziona (IL); Mordechay Golan, Herzliya (IL); Menachem Tipris, Raanana (IL)

(21) Appl. No.: 14/184,489

(22) Filed: Feb. 19, 2014

Related U.S. Application Data
(63) Continuation of application No. 13/979,064.
(60) Provisional application No. 61/431,138, filed on Jan. 10, 2011.

(51) Int. Cl. H01L 31/042

(52) U.S. Cl. CPC H01L 31/0422
USPC 136/246

(57) ABSTRACT

A solar electricity generator including an array of solar electricity generating elements, a solar energy concentrating element operative to transmit concentrated solar radiation from the sun onto the array, voltage measuring functionality operative to measure at least one of a total row voltage generated by at least one row of the electricity generating elements in the array and a total column voltage generated by at least one column of the electricity generating elements in the array.

### REFERENCE TO RELATED APPLICATIONS

Reference is made to U.S. Provisional Patent Application Ser. No. 61/431,138, filed Jan. 10, 2011 and entitled “CPV TRACKING USING PARTIAL CELL VOLTAGES”, the disclosure of which is hereby incorporated by reference and priority of which is hereby claimed pursuant to 37 CFR 1.78(a) (4) and (5)(i).

Reference is also made to the following patents and patent applications, owned by assignee, the disclosures of which are hereby incorporated by reference:

U.S. Published Patent Application Nos.: 2009/0065045, 2010/0252091 and 2011/0061719; and

U.S. patent application Ser. No. 12/947,483.

### FIELD OF THE INVENTION

The present invention relates to concentrated photovoltaic power generation.

### BACKGROUND OF THE INVENTION

The following patents, patent publications and publications are believed to represent the current state of the art:

U.S. Pat. Nos. 7,834,303 and 7,884,308; and

U.S. Published Patent Application Nos.: 2008/0087321, 2009/0145480, 2010/0059042 and 2010/0059043.

### SUMMARY OF THE INVENTION

The present invention seeks to provide improved systems and methods of concentrated photovoltaic power generation.

There is thus provided in accordance with a preferred embodiment of the present invention a solar electricity generator including an array of solar electricity generating elements, a solar energy concentrating element operative to transmit concentrated solar radiation from the sun onto the array, voltage measuring functionality operative to measure at least one of a total row voltage generated by at least one row of the electricity generating elements in the array and a total column voltage generated by at least one column of the electricity generating elements in the array, vertical positioning functionality operative, in response to ascertaining by the voltage measuring functionality that a first total row voltage generated by a first multiplicity of the rows is less than a second total row voltage generated by a second multiplicity of rows, to generally vertically reposition the solar energy concentrating element thereby to increase exposure of the first multiplicity of the rows to solar radiation transmitted from the sun by the solar energy concentrating element, and horizontal positioning functionality operative, in response to ascertaining by the voltage measuring functionality that a first total column voltage generated by a first multiplicity of the columns is less than a second total column voltage generated by a second multiplicity of columns, to horizontally reposition the solar energy concentrating element thereby to increase exposure of the first multiplicity of the columns to solar radiation transmitted from the sun by the solar energy concentrating element.

Preferably, the solar energy concentrating element is a concave reflecting surface. Alternatively, the solar energy concentrating element is a concentrating lens.

Preferably, the solar electricity generator also includes solar tracking functionality operative to utilize astronomical information to rotate and position the energy concentrating element opposite the sun throughout the day. Preferably, the solar electricity generating elements are serially connected. Preferably, the voltage measuring functionality is operative to continuously measure the row and column voltages throughout the day.

There is also provided in accordance with another preferred embodiment of the present invention a method for generating solar electricity including transmitting concentrated solar radiation from the sun onto an array of solar electricity generating elements, measuring at least one of a total row voltage generated by at least one row of the electricity generating elements in the array and a total column voltage generated by at least one column of the electricity generating elements in the array, in response to ascertaining by the measuring that a first total row voltage generated by a first multiplicity of the rows is less than a second total row voltage generated by a second multiplicity of rows, to generally vertically reposition the solar energy concentrating element thereby to increase exposure of the first multiplicity of the rows to solar radiation transmitted from the sun by the solar energy concentrating element, and in response to ascertaining by the measuring that a first total column voltage generated by a first multiplicity of the columns is less than a second total column voltage generated by a second multiplicity of columns, to horizontally reposition the solar energy concentrating element thereby to increase exposure of the first multiplicity of the columns to solar radiation transmitted from the sun by the solar energy concentrating element.

Preferably, the measuring includes continuously measuring throughout the day.

### BRIEF DESCRIPTION OF THE DRAWINGS

The present invention will be understood more fully from the following detailed description, taken in conjunction with the drawings in which:

FIG. 1 is a simplified pictorial illustration of a solar electricity generator constructed and operative in accordance with a preferred embodiment of the invention;

FIGS. 2A and 2B are simplified pictorial illustrations of steps in the operation of the solar electricity generator of FIG. 1; and

FIGS. 3A and 3B are simplified pictorial illustration of further steps in the operation of the solar electricity generator of FIG. 1.

### DETAILED DESCRIPTION OF PREFERRED EMBODIMENTS

Reference is now made to FIG. 1, which is a simplified pictorial illustration of a solar electricity generator constructed and operative in accordance with a preferred embodiment of the invention. The solar electricity generator of FIG. 1 preferably includes an array of solar electricity generating elements, a solar energy concentrating element operative to transmit concentrated solar radiation from the sun onto the array, and voltage measuring functionality operative to measure at least one of a total row voltage generated by at least one row of the electricity generating elements in the array and a total column voltage generated by at least one column of the electricity generating elements in the array.

It is a particular feature of the present invention that the solar electricity generator of FIG. 1 preferably includes vertical positioning functionality operative, in response to ascertaining by the voltage measuring functionality that a first total row voltage generated by a first multiplicity of the rows is less than a second total row voltage generated by a second multiplicity of rows, to generally vertically reposition the solar energy concentrating element thereby to increase exposure of the first multiplicity of the rows to solar radiation transmitted from the sun by the solar energy concentrating element.

Similarly, the solar electricity generator of FIG. 1 also preferably includes horizontal positioning functionality operative, in response to ascertaining by the voltage measuring functionality that a first total column voltage generated by a first multiplicity of the columns is less than a second total column voltage generated by a second multiplicity of columns, to horizontally reposition the solar energy concentrating element thereby to increase exposure of the first multiplicity of the columns to solar radiation transmitted from the sun by the solar energy concentrating element.

As shown in FIG. 1, a solar electricity generator 100 includes a solar energy concentrating element, such as a concave reflecting surface 102. Alternatively, the solar energy concentrating element may be, for example, a concentrating lens.

Preferably, a solar tracking system 104 such as a PESOS® SFC 30 Tracking System, commercially available from PAIRAN Elektronik GmbH of Göttingen, Germany, is provided for rotating and positioning reflecting surface 102 opposite the sun throughout the day. Preferably, tracking system 104 utilizes astronomical information to position reflecting surface 102 opposite the sun.

An array 110 of solar electricity generating elements is preferably mounted generally opposite reflecting surface 102, thereby being arranged to absorb solar radiation reflected thereupon by reflecting surface 102. Preferably, array 110 is divided into four quadrants of solar electricity generating elements, which quadrants are designated by reference numerals 112, 114, 116 and 118. Quadrants 112, 114, 116 and 118 are preferably serially connected by connecting elements 122, 124 and 126, whereby the total voltage generated by array 110 is provided between terminals 128 and 130.

Voltage meter 132 is preferably provided for measuring electric voltage V1 generated by quadrant 112 of solar electricity generating elements between terminal 128 and connecting element 122. Voltage meter 134 is preferably provided for measuring electric voltage V2 generated by quadrant 114 of solar electricity generating elements between connecting element 122 and connecting element 124. Voltage meter 136 is preferably provided for measuring electric voltage V3 generated by quadrant 116 of solar electricity generating elements between connecting clement 124 and connecting element 126. Voltage meter 138 is preferably provided for measuring electric voltage V4 generated by quadrant 118 of solar electricity generating elements between connecting element 126 and terminal 130.

It is appreciated that voltage meters 132, 134, 136 and 138 preferably continuously measure voltages V1, V2, V3 and V4 throughout the day.

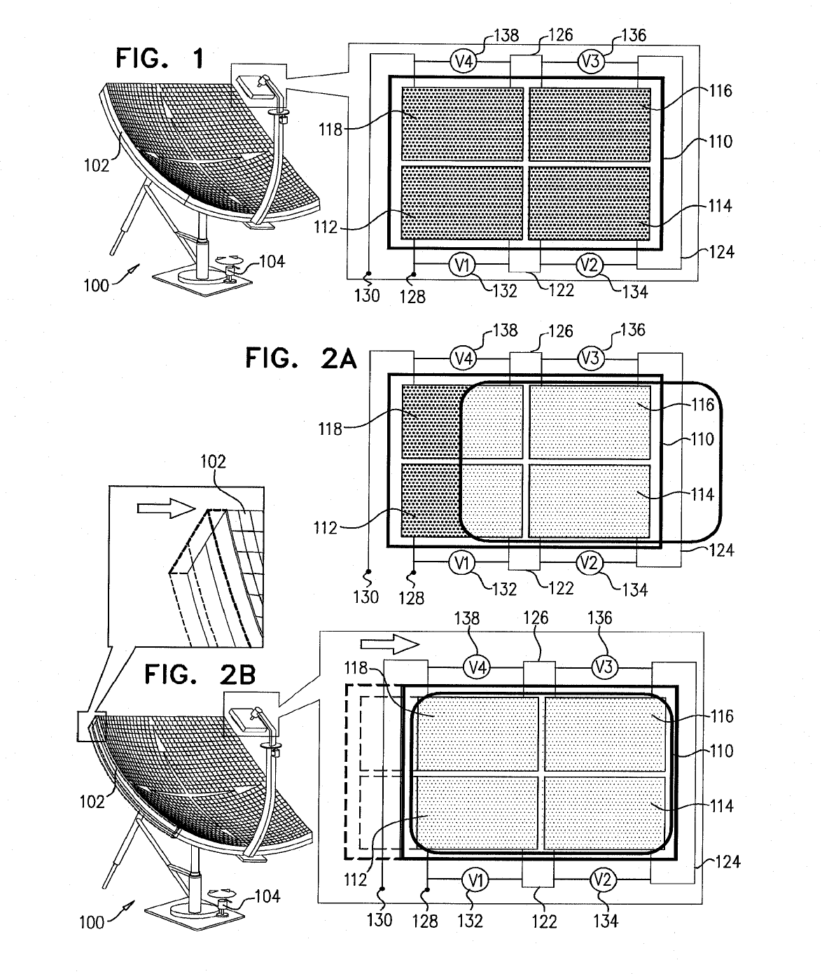

Reference is now made to FIGS. 2A and 213, which are simplified pictorial illustrations of steps in the operation of the solar electricity generator of FIG. 1. As shown in FIG. 2A, solar radiation reflected by reflecting surface 102 is not entirely aligned with the surface of array 110, and a portion of the solar radiation reflected by reflecting surface 102 does not impinge on array 110. Furthermore, the misalignment of the solar radiation reflected by reflecting surface 102 with array 110 causes the quadrants 112 and 118 to be impinged with less radiation quadrants 114 and 116, thereby causing the combined generated electric voltages V1 and V4 of respective quadrants 112 and 118 to be lower than the combined generated electric voltages V2 and V3 of respective quadrants 114 and 116.

As mentioned hereinabove, it is a particular feature of the present invention that solar electricity generator 100 preferably includes horizontal positioning functionality operative, in response to ascertaining that the combined generated electric voltages V1 and V4 are less than the combined generated electric voltages V2 and V3, to horizontally reposition reflecting surface 102 opposite the sun and to thereby increase exposure of quadrants 112 and 118 to solar radiation reflected from the sun by reflecting surface 102.

It is appreciated that the horizontal positioning functionality is typically provided in addition to the solar tracking functionality provided by solar tracking system 104, and may be either integrated within solar tracking system 104 or provided in addition to solar tracking system 104. However, it is also appreciated that the horizontal positioning functionality utilizes information provided solely by voltage meters 132, 134, 136 and 138 and does not require information regarding the relative position of solar electricity generator 100 and the sun in order to reposition reflecting surface 102 opposite the sun.

As shown in FIG. 2B, after generally rightward repositioning of reflecting surface 102 by the horizontal positioning functionality, quadrants 112, 114, 116 and 118 are all generally equally exposed to solar radiation reflected from the sun by reflecting surface 102, thereby causing subsequent measurements of generated electric voltages V1, V2, V3 and V4 to be generally equal.

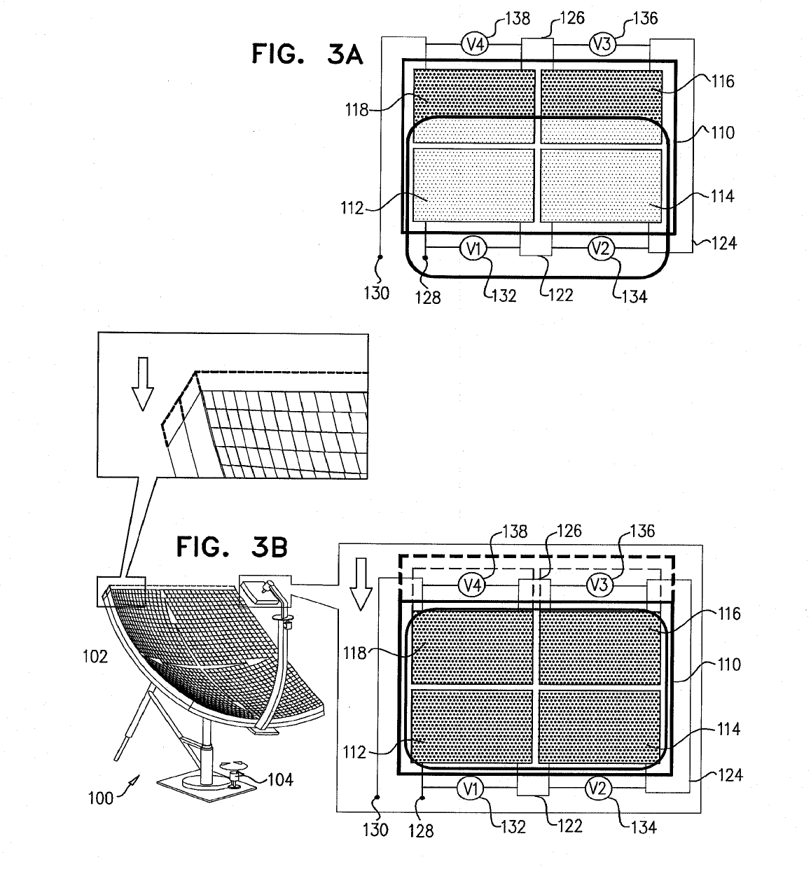

Reference is now made to FIGS. 3A and 3B, which are simplified pictorial illustration of further steps in the operation of the solar electricity generator of FIG. 1. As shown in FIG. 3A, solar radiation reflected by reflecting surface 102 is not entirely aligned with the surface of array 110, and a portion of the solar radiation reflected by reflecting surface 102 does not impinge on array 110. Furthermore, the misalignment of the solar radiation reflected by reflecting surface 102 with array 110 causes the quadrants 116 and 118 to be impinged with less radiation quadrants 112 and 114, thereby causing the combined generated electric voltages V3 and V4 of respective quadrants 116 and 118 to be lower than the combined generated electric voltages V1 and V2 of respective quadrants 112 and 114.

As mentioned hereinabove, it is a particular feature of the present invention that solar electricity generator 100 preferably includes vertical positioning functionality operative, in response to ascertaining that the combined generated electric voltages V3 and V4 are less than the combined generated electric voltages V1 and V2, to vertically reposition reflecting surface 102 opposite the sun and to thereby increase exposure of quadrants 116 and 118 to solar radiation reflected from the sun by reflecting surface 102.

It is appreciated that the vertical positioning functionality is typically provided in addition to the solar tracking functionality provided by solar tracking system 104, and may be either integrated within solar tracking system 104 or provided in addition to solar tracking system 104. However, it is also appreciated that the vertical positioning functionality utilizes information provided solely by voltage meters 132, 134, 136 and 138 and does not require information regarding the relative position of solar electricity generator 100 and the sun in order to reposition reflecting surface 102 opposite the sun.

As shown in FIG. 3B, after generally downward repositioning of reflecting surface 102 by the vertical positioning functionality, quadrants 112, 114, 116 and 118 are all generally equally exposed to solar radiation reflected from the sun by reflecting surface 102, thereby causing subsequent measurements of generated electric voltages V1, V2, V3 and V4 to be generally equal.

It will be appreciated by persons skilled in the art that the present invention is not limited by what has been particularly shown and described hereinabove. Rather the scope of the present invention includes both combinations and subcombinations of various features described hereinabove as well as variations and modifications thereof which are not in the prior art.

1. A solar electricity generator comprising:
an array of solar electricity generating elements;
a solar energy concentrating element operative to transmit concentrated solar radiation from the sun onto said array;
voltage measuring functionality operative to measure at least one of a total row voltage generated by at least one row of said electricity generating elements in said array and a total column voltage generated by at least one column of said electricity generating elements in said array;
vertical positioning functionality operative, in response to ascertaining by said voltage measuring functionality that a first total row voltage generated by a first multiplicity of said rows is less than a second total row voltage generated by a second multiplicity of rows, to generally vertically reposition said solar energy concentrating element thereby to increase exposure of said first multiplicity of said rows to solar radiation transmitted from the sun by said solar energy concentrating element; and
horizontal positioning functionality operative, in response to ascertaining by said voltage measuring functionality that a first total column voltage generated by a first multiplicity of said columns is less than a second total column voltage generated by a second multiplicity of columns, to horizontally reposition said solar energy concentrating element thereby to increase exposure of said first multiplicity of said columns to solar radiation transmitted from the sun by said solar energy concentrating element.

2. A solar electricity generator according to claim 1 and wherein said solar energy concentrating element is a concave reflecting surface.

3. A solar electricity generator according to claim 1 and wherein said solar energy concentrating element is a concentrating lens.

4. A solar electricity generator according to claim 1 and also comprising solar tracking functionality operative to utilize astronomical information to rotate and position said energy concentrating element opposite the sun throughout the day.

5. A solar electricity generator according to claim 1 and wherein said solar electricity generating elements are serially connected.

6. A solar electricity generator according to claim 1 and wherein said voltage measuring functionality is operative to continuously measure said row and column voltages throughout the day.

7. A method for generating solar electricity comprising:
transmitting concentrated solar radiation from the sun onto an array of solar electricity generating elements;
measuring a total row voltage generated by at least one row of said electricity generating elements in said array and a total column voltage generated by at least one column of said electricity generating elements in said array;
in response to ascertaining by said measuring that a first total row voltage generated by a first multiplicity of said rows is less than a second total row voltage generated by a second multiplicity of rows, to generally vertically reposition said solar energy concentrating element thereby to increase exposure of said first multiplicity of said rows to solar radiation transmitted from the sun by said solar energy concentrating element; and
in response to ascertaining by said measuring that a first total column voltage generated by a first multiplicity of said columns is less than a second total column voltage generated by a second multiplicity of columns, to horizontally reposition said solar energy concentrating element thereby to increase exposure of said first multiplicity of said columns to solar radiation transmitted from the sun by said solar energy concentrating element.

8. A method for generating solar electricity according to claim 7 and wherein said measuring comprises continuously measuring throughout the day.
